(19) United States
(12) Patent Application Publication
(10) Pub. No.: US 2011/0265711 A1
(43) Pub. Date: Nov. 3, 2011

(54) VACUUM CHAMBER FOR COATING INSTALLATIONS AND METHOD FOR PRODUCING A VACUUM CHAMBER FOR COATING INSTALLATIONS

(75) Inventor: Markus Esselbach, Feldkirch (AT)

(73) Assignee: OERLIKON TRADING AG, TRUBBACH, Trubbach (CH)

(21) Appl. No.: 13/141,188

(22) PCT Filed: Oct. 28, 2009
(86) PCT No.: PCT/EP2009/007703

§ 371 Date: Jun. 21, 2011

Related U.S. Application Data
(60) Provisional application No. 61/146,016, filed on Jan. 21, 2009.

(30) Foreign Application Priority Data
Feb. 8, 2009 (DE) 10 2009 007 897.5

(51) Int. Cl. C23C 14/00; B23P 11/00

(52) U.S. Cl. 118/50; 29/428

(57) ABSTRACT

A vacuum chamber (1) for coating installations is provided, wherein the vacuum chamber (1) has a bottom plate (6) and a top plate (2), which are connected to each other by struts (4) running substantially perpendicularly to the bottom plate (6) and the top plate (2), wherein a plurality of openings (9) are defined by the bottom plate (6), the top plate (2) and the struts (4), and wherein at least a portion of a front edge (15′) of the bottom plate (6) and a portion of the front edge (15) of the top plate (2) form together with two struts (4) a sealing area, running around one opening (9) of the multiplicity of openings (9), for an insert plate (8) that can be inserted into the opening (9). In addition, a method for producing a vacuum chamber (1) for coating installations is provided, comprising the following steps: putting together a frame which has a bottom plate (6), a top plate (2) and struts (4), which connect the bottom plate (6) and the top plate (2), and welding the bottom plate (6) and the top plate (2) to the struts (4).

The present invention relates to a vacuum chamber for coating installations according to the preamble of claim 1 as well as a method for producing a vacuum chamber for coating installations according to the preamble of claim 13.

The coating methods known as PVD or CVD designate for instance coating methods under vacuum conditions. In the case of PVD (physical vapor deposition), the coating process is based essentially on physical deposition of material on a workpiece to be coated. In the case of CVD (chemical vapor deposition), the coating method is based essentially on chemical reactions. Both methods have in common that they often take place under high vacuum conditions (HV, 10⁻³ mbar to 10⁻⁷ mbar) or under ultra high vacuum conditions (UHV, 10⁻⁷ mbar to 10⁻¹² mbar). In the frame of the present invention, the state of a fluid under vacuum in a volume is to be designated with a pressure that is lower than 10⁻¹ mbar.

As a general rule, to generate a vacuum a fluid is pumped out of a tightly sealed chamber. The chamber is typically made of an integrally formed chamber body, most often of high-quality steel. Thanks to such an integrally formed design of the vacuum chamber, possible leaks can be prevented and additionally a good vacuum can be created.

Using an integrally formed chamber body has however a disadvantage if modifications are to be made to the installation, since these can be effected on the integrally formed chamber body only with considerable efforts (separating, welding etc.).

In order to solve this problem, DE9404022 proposes a vacuum chamber that is not made integrally but in a modular fashion. In this case, the vacuum chamber is divided in several function levels (target, source and pump levels) formed through a flange composition. By providing a detachable connection of the flange-joint connected areas, modifications to the structure of the vacuum chamber are simplified and the costs for modifying the vacuum chamber are also reduced. Furthermore, for the purpose of later expansions, the upper and lower closing can occur with flange-connected covers.

Although providing areas connected with flange joints according to the vacuum chamber described in DE 94 940 22 affords increased flexibility as regards changes or modifications of the vacuum chamber by comparison with integrally-formed vacuum chambers, the structural properties of the vacuum chamber pose a problem since it must be ensured that the chamber built by means of the flange-connected elements offers the required stability.

In contrast thereto, in an earlier application of the same applicant a vacuum chamber is disclosed which is built as a frame construction, wherein the base area of the frame and the struts are made of one piece. Additionally, the struts are formed by bending protruding arms of the panel vertically upwards and therefore in these areas no welding is necessary. Thus only the frame elements of the doors as well as of the cover panel are welded. The frame forms a structure for the chamber into which insert plates can be inserted to complete the chamber. It is possible to pre-assemble onto the insert plates attachments or in-built devices, such as for example pumps, target or source. The insert plates are connected with the frame mechanically and vacuum-tight. For the manufacture of several different vacuum chambers, frames can be standardized as modules in a large number and thus be produced at low cost. In the case of specific customer requirements, the frame no longer needs to be worked upon at all, as the customer specifications can be fully taken into account by adapting the insert plates. The functional elements provided for this purpose, such as for example target, source or vacuum pump, but for example also vision panels, can be arranged from one chamber to the next in a different manner in relation to one another.

However, in the construction—described above and known in the state of the art—of a vacuum chamber, one disadvantage lies in the fact that the panels necessary for building the frame must be sufficiently thin to allow the struts or the shell part of the frame to be bent, which then results in a reduced stability of the frame.

The task of the present invention is thus to provide a vacuum chamber that can be adapted to changes and modifications in a flexible manner, but which at the same time has increased stability.

According to the invention, the task is solved by a vacuum chamber for coating installations with the characteristics according to claim 1 as well as by a method for producing a vacuum chamber for coating installations with the characteristics according to claim 13. Advantageous further embodiments are defined in the respective dependent claims.

According to the invention, a vacuum chamber for coating installations is provided, wherein the vacuum chamber has a bottom plate and a top plate, which are connected to each other by struts running substantially perpendicularly to the bottom plate and the top plate, wherein a plurality of openings are defined by the bottom plate, the top plate and the struts, wherein at least a portion of a front edge of the bottom plate and a portion of the front edge of the top plate form together with two struts a sealing area, running around one opening of the multiplicity of openings, for an insert plate that can be inserted into the opening.

Since the top plate and the bottom plate are of sufficient thickness, the front edges of these plates themselves can be used as sealing mating parts for the insert plates. Furthermore, using the front edges of the bottom plate and of the top plate as sealing surface affords the advantage that no additional panels need to be welded to the frame construction. Furthermore, integrating the front edges of the top plate and of the bottom plate as sealing surface makes it possible for the flange plates resp. insert plates to be made markedly taller for the same height of the vacuum chamber.

Additionally, threaded holes that serve for example to fasten the inserted insert plates by means of screws can be provided directly in the top plate and in the bottom plate, which results in lower production costs without any loss of precision whatsoever.

Because individual rods are used as struts for the frame that are, to begin with, separate from the bottom plate and the top plate and only connected tightly with the latter—for example by welding—when they are assembled, the production of the frame does not require a step of bending and the struts can be made in a thickness that guarantees increased stability.

According to a preferred embodiment, the bottom plate and/or the top plate have a thickness of at least 3 cm. This results in an increased stability with respect to the load of the vacuum chamber generated because of the vacuum.

The bottom plate and/or the top plate is preferably made in the shape of a quadrangular panel. An octagonal or decagonal shape is particularly preferred.

According to another preferred embodiment, the bottom plate, the top plate and the struts form a prismatic body.

According to yet another preferred embodiment, the struts are made each with a polygonal section, in particular a pentagonal profile. By providing the struts with a pentagonal cross section, which can be achieved in particular by milling, the stability of the vacuum chamber can be further optimized in respect of the forces arising when the vacuum chamber is evacuated. Additionally, the struts made in a pentagonal profile have low spatial requirements in view of the vacuum chamber's volume.

The bottom plate and/or the top plate are preferably provided with centering holes at the positions where the respective struts can be fastened thereto, which makes the assembly of the frame easier.

It is furthermore preferable if the bottom plate and/or the top plate are provided with a tapered edge at the positions where the respective struts can be fastened thereto, for a subsequent welding seam.

Providing each of the struts with at least one threaded hole is particularly preferred. This allows the insert plates to be screwed onto the struts by means of screws from the outside, which ensures a good sealing connection between the insert plates and the frame without any risk of possible leakages. This configuration further enables the insert plates to be arranged abutting next to one another, which results in a space saving of for example 4 to 5 cm by comparison with the systems known in the state of the art. This again has the consequence that for the same diameter of the vacuum chamber, more insert plates can be provided.

According to a further preferred embodiment, the insert plates can be affixed to the struts from the outside, they can in particular be screwed thereto by means of screws, which creates a tight yet detachable connection. Additional sealing material, for example a rubber seal, can be used between the frame elements of the vacuum chamber and the insert elements.

It is furthermore preferred for the struts to be chamfered at their respective ends, which considerably simplifies the application of the welding seam.

The insert plates of the vacuum chamber are preferably made of aluminum. This results in lower production costs.

According to yet a further preferred embodiment, the vacuum chamber has a door for opening and closing the vacuum chamber.

According to the invention, a method for producing a vacuum chamber for coating installations is furthermore provided, comprising the following steps: putting together a frame which has a bottom plate, a top plate and struts, which connect the bottom plate and the top plate, and welding the bottom plate and the top plate to the struts. Thanks to the inventive method, a vacuum chamber with a high stability and great flexibility as regards modifications can be achieved in an easy way.

In order to make the step of welding easier, the already assembled frame is held during welding in a supporting structure. Thanks to this, the frame remains in a defined shape and warpage of the frame arising because of the welding is minimized.

After welding, the frame is preferably milled and subsequently sandblasted.

The invention will be explained hereinafter in detail by means of one embodiment and with the aid of drawings, which show:

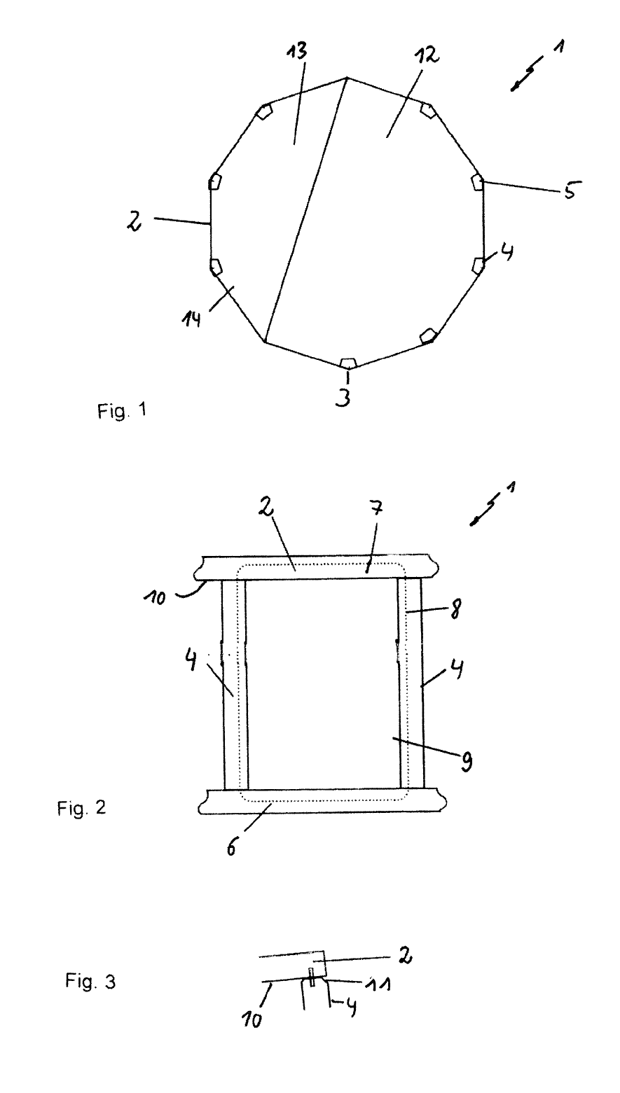

FIG. 1 a top view of a vacuum chamber according to one embodiment;

FIG. 2 a side view of the vacuum chamber represented in FIG. 1;

FIG. 3 a detailed view of a connection point of a strut with a section of the top plate.

FIG. 1 shows a top view of a vacuum chamber 1 resp. of the top plate 2 forming the top closing-off element of the vacuum chamber 1. It must be noted that the bottom plate (not represented here) is executed essentially like the top plate 2, so that both plates together with the struts and the insert plates (also not represented here) form a vacuum chamber 1 in the shape of a prism. The top plate 2 according to this embodiment is formed as a decagon resp. as a decagonal plate. At each corner 3 of the top plate 2, a strut 4 is placed that connects the top plate 2 with the bottom plate.

The position of the strut 4 at the underside (not visible here) of the top plate 2 resp. its outer outline is represented schematically by respective pentagons 5. The cover plate 2 and also the bottom plate can have, at the places where the struts 4 are placed, a borehole (not represented here) for a centering pin as well as a tapered edge (also not represented in the figure) for a subsequent welding seam.

To make the top plate 2 and the bottom plate, it is possible to use water jet cutting, through which the plates can be made in the desired shape.

Furthermore, it can be observed in FIG. 1 that the top plate 2 is divided into a first portion 12 and a second portion 13, wherein the second portion 13 is part of a door 14 that is provided for opening and closing the vacuum chamber 1.

FIG. 2 shows a side view of the vacuum chamber 1 represented in FIG. 1. An essential characteristic of the inventive vacuum chamber 1 is that the top plate 2 and the bottom plate 6 are each sufficiently thick so that their respective front edges 15, 15′ form together with two struts 4 a circumferentially sealing area 7 for an insert plate 8 (schematically represented in the figure through the dotted line) that can be inserted into an opening 9. For example, the thickness of the top plate 2 and of the bottom plate 6 can measure 3 cm. This results in an increased stability with respect to the load of the vacuum chamber generated because of the vacuum. Using the front edges 15, 15′ of the bottom plate 6 and of the top plate 2 as sealing surface 7 means that no additional panels need to be welded to the construction. Furthermore, threaded holes (not represented) can be made directly in the top plate 2 and in the bottom plate 6, which results in lower production costs whilst maintaining a high precision.

The struts 4 are made of massive metal rods that, in the embodiment represented here, are milled in the pentagonal shape already discussed above. They are thus optimized for stability in respect of the forces arising when the vacuum chamber 1 is evacuated and have reduced spatial requirements in view of the vacuum chamber's volume.

The insert plates 8, in the embodiment, screwed to the struts 4 from the outside.

FIG. 3 finally shows a detailed view of a connection point of a strut 4 with a section of the top plate 2. As can be seen in the figure, the strut 4 is strongly chamfered at its end portion 11 adjacent to the underside 10 of the top plate 2, which considerably simplifies the application of the welding seam. The end portion of the strut 4 adjacent to the bottom plate 6 is executed similarly to the end portion 11.

To build the vacuum chamber, the frame is assembled, consisting of the top plate 2, the bottom plate 6 and the struts 4 described above, and a door flange is attached. It is advantageous in this case for the frame to be held by a supporting structure.

Following this, the top plate 2 and the bottom plate 6 are welded with the struts 4. The plates and the struts are sized in excess so that they can later be milled to dimension. Unevenness from the welding can thus easily be removed by milling.

In the event that cooling is required because of the high processing temperatures, it would be limited to the top plate 2 and the bottom plate 6 resp. bottom flange, since the lateral parts resp. insert plates 8 are made completely of aluminum.

After welding, the supporting structure is momentarily loosened. This allows the system to relax. In order to be able to perform if necessary subsequent milling work, the supporting structure is fastened again. Following this, the frame thus generated can then be cleaned for example by means of sandblasting. In similar manner, the door 14 can for example be made.

It must be noted that the frame produced by means of the inventive method has a greater stability by comparison with the frames known in the state of the art, although the vacuum chamber achieves its final stability through the insert plates 8, made of aluminum, that are attached to the frame.

### REFERENCE SIGNS IN THE FIGURES

1 vacuum chamber

2 top plate

3 corner

4 strut

5 pentagon

6 bottom plate

7 sealing area

8 insert plate

9 opening

10 underside of the top plate

11 end portion of the strut

12 first portion

13 second portion

14 door

15,15′ front edge

1. Vacuum chamber (1) for coating installations, wherein the vacuum chamber (1) has a bottom plate (6) and a top plate (2), which are connected to each other by struts (4) running substantially perpendicularly to the bottom plate (6) and the top plate (2), wherein a plurality of openings (9) are defined by the bottom plate (6), the top plate (2) and the struts (4),
characterized in that
at least a portion of a front edge (15′) of the bottom plate (6) and a portion of the front edge (15) of the top plate (2) form together with two struts (4) a sealing area, running around one opening (9) of the multiplicity of openings (9), for an insert plate (8) that can be inserted into the opening (9).

2. Vacuum chamber (1) according to claim 1, characterized in that the bottom plate (6) and/or the top plate (2) each have a thickness of at least 3 cm.

3. Vacuum chamber (1) according to claim 1 or 2, characterized in that the bottom plate (6) and/or the top plate (2) are made in the form of a multi-angular plate.

4. Vacuum chamber (1) according to one or several of the claims 1 to 3, characterized in that the bottom plate (6), the top plate (2) and the struts (4) form a prismatic body.

5. Vacuum chamber (1) according to one or several of the claims 1 to 4, characterized in that the struts (4) are made in a polygonal section, in particular with a pentagonal profile.

6. Vacuum chamber (1) according to one or several of the claims 1 to 5, characterized in that the bottom plate (6) and/or the top plate (2) are provided with centering holes at the positions where the respective struts (4) can be fastened thereto.

7. Vacuum chamber (1) according to one or several of the claims 1 to 6, characterized in that the bottom plate (6) and/or the top plate (2) are provided with a tapered edge at the positions where the respective struts can be fastened thereto.

8. Vacuum chamber (1) according to one or several of the claims 1 to 7, characterized in that the struts (4) are each provided with at least one threaded hole.

9. Vacuum chamber (1) according to one or several of the claims 1 to 8, characterized in that the insert plates (8) can be fastened to the struts (4) from the outside and can in particular be screwed thereto by means of screws.

10. Vacuum chamber (1) according to one or several of the claims 1 to 9, characterized in that the struts (4) are chamfered at their respective ends (11).

11. Vacuum chamber (1) according to one or several of the claims 1 to 10, characterized in that the insert plates (8) are made of aluminum.

12. Vacuum chamber (1) according to one or several of the claims 1 to 11, characterized in that a door (14) for opening and closing the vacuum chamber (1) is provided.

13. Method for producing a vacuum chamber (1) for coating installations, characterized in that the method comprises the following steps:
putting together a frame which has a bottom plate (6), a top plate (2) and struts (4), which connect the bottom plate (6) and the top plate (2), and
welding the bottom plate (6) and the top plate (2) to the struts (4).

14. Method according to claim 13, characterized in that the assembled frame is held during welding in a supporting structure.

15. Method according to claim 13 or 14, characterized in that after welding, the frame is milled and subsequently sandblasted.
